(19) United States
(12) Patent Application Publication
(10) Pub. No.: US 2018/0165227 A1
(43) Pub. Date: Jun. 14, 2018

(54) Portable Entertainment System

(71) Applicant: Franklin Maldonado, Webster, MA (US)

(72) Inventor: Franklin Maldonado, Webster, MA (US)

(21) Appl. No.: 15/893,385

(22) Filed: Feb. 9, 2018

Related U.S. Application Data
(63) Continuation-in-part of application No. 15/268,236, filed on Sep. 16, 2016.
Application No. 15/268,236 is a continuation-in-part of application No. 29/578,132, filed on Sep. 19, 2016.
Application No. 29/578,132 is a continuation-in-part of application No. 29/632,599, filed on Jan. 9, 2018.

(51) Int. Cl. G06F 13/10; H04M 1/04; A63F 13/24; A63F 13/92; A63F 13/235; A63F 13/26; G06F 1/16; G06F 1/20; H05K 7/20

(52) U.S. Cl. CPC G06F 13/102; H04M 1/04; A63F 13/24; A63F 13/92; A63F 13/235; A63F 13/42; G06F 1/1632; G06F 1/1684; G06F 1/203; H05K 7/20136; A63F 13/26

(57) ABSTRACT

A portable entertainment system has a base unit and a remote computing device. The base unit has an electronics apparatus, the electronics apparatus has a base processing module, the base processing module has a base central processing unit and a base graphics processing unit, the base central processing unit and the base graphics processing unit are electrically connected with each other, the remote computing device has a remote processing module, the remote processing module has a remote central processing unit and a remote graphics processing unit, and the remote central processing unit and the remote graphics processing unit are electrically connected with each other. When the base unit and the remote computing device are electrically connected with each other, the base central processing unit and the remote central processing unit are coupled with each other, the base graphics processing unit is active, and the remote graphics processing unit is inactive.

The current application claims a priority to the U.S. Non-Provisional patent application Ser. No. 15/268,236 filed on Sep. 16, 2016, the U.S. Design patent application Ser. No. 29/578,132 filed on Sep. 19, 2016, and the U.S. Design patent application Ser. No. 29/632,599 filed on Jan. 9, 2018.

### FIELD OF THE INVENTION

The present invention relates generally to an entertainment industry. More particularly, the present invention relates to a system for interfacing electronic devices to create an adaptable and portable entertainment system.

### BACKGROUND OF THE INVENTION

Since the introduction of computers, the entertainment sector has seen offerings progress from single purpose devices to all-in-one solutions. It is no longer enough to offer only a dock, or a gaming solution. Rather consumers demand an entire entertainment system with multiple applications. Moreover, no mirror imaging hardware solution has been able to solve the smartphone overheating problem at the time of mirror imaging content from a smartphone to a larger display. Particularly, the applications/software run by the smartphone will evolve alongside of its chips and then back to heating square one.

The present invention seeks to offer such a solution by combining several electronics that allow for both gaming and multimedia playback, amongst other capabilities. The present invention introduces a base unit, a handheld controller, a remote computing device and a wireless earbud device which can interact with one another in several ways to support the aforementioned features. The base unit is able to support both the handheld controller, the remote computing device and the wireless earbud device. In which, the remote computing device (smart remote control) is held (docked) into the handheld controller, which serves as the brains of the handheld controller. This allows for charging of the handheld controller and the remote computing device. This also enables outputting multimedia from the remote computing device to connected apparatus, such as televisions and speakers.

The handheld controller interfaces with the remote computing device to enable gameplay, for example, with visual data being displayed through the remote computing device. However, the whole purpose of the present invention is the actual interactivity and unification with a smartphone or tablet device, achieved thanks to both direct and indirect (i.e. wired or wireless) connections between the handheld controller and the base unit as well as receptacles for said smartphone or tablet. The handheld controller also emphasizes ergonomic improvements, providing elliptical grooves along several inputs which are more comfortable for a person's fingers.

Furthermore, instead of attacking the issue from the inside of the smartphone, the present invention is tackling the GPU load from the outside. The present invention solved this task by adding an external dedicated graphics card that will handle all GPU aspect of the assembly topology. In which, it will relieve all geometrical processing (GPU load) from the smartphone at the time of connection.

The improvements offered by the present invention are further detailed and expanded upon below.

### BRIEF DESCRIPTION OF THE DRAWINGS

FIG. 1 is a perspective view of a base unit of the present invention.

FIG. 2 is a top plan view of the base unit of the present invention.

FIG. 3 is a bottom plan view of the base unit of the present invention.

FIG. 4 is a rear elevational view of the base unit of the present invention.

FIG. 5 is a front elevational view of the base unit of the present invention.

FIG. 6 is a right-side elevational view of the base unit of the present invention.

FIG. 7 is a left-side elevational view of the base unit of the present invention.

FIG. 8 is a perspective view of a remote computing device docked into a handheld controller of the present invention.

FIG. 9 is a bottom rear perspective view of the handheld controller of the present invention.

FIG. 10 is a top plan view of the remote computing device docked into the handheld controller of the present invention.

FIG. 11 is a front elevational view of the remote computing device docked into the handheld controller of the present invention.

FIG. 12 is a magnified view showing the remote computing device docked into the handheld controller of the present invention.

FIG. 13 is a magnified view showing a recess (a remote computing device receptacle) of the handheld controller of the present invention.

FIG. 14 is a perspective view of the remote computing device of the present invention.

FIG. 15 is a front elevational view of the remote computing device of the present invention.

FIG. 16 is left-side elevational view of the remote computing device of the present invention.

FIG. 17 is a right side elevational view of the remote computing device of the present invention.

FIG. 18 is a perspective view of the base unit with a cooling apparatus of the present invention.

FIG. 19 is a perspective view of the handheld controller with two vibrational motors of the present invention.

FIG. 20 is a top plan view of a wireless earbud device docked into the handheld controller with another two vibrational motors of the present invention.

FIG. 21 is a top plan view of the handheld controller with a supporting frame of the present invention.

FIG. 22 is a top plan view of another remote computing device docked into the handheld controller of the present invention.

FIG. 23 is a diagram showing electrical and electronic connections of the base unit of the present invention.

FIG. 24 is a diagram showing electrical and electronic connections of the handheld controller of the present invention.

FIG. 25 is a diagram showing electrical and electronic connections of the remote computing device of the present invention.

FIG. 26 is a diagram showing electrical and electronic connections of the wireless earbud device of the present invention.

### DETAIL DESCRIPTIONS OF THE INVENTION

All illustrations of the drawings are for the purpose of describing selected versions of the present invention and are not intended to limit the scope of the present invention. The present invention is to be described in detail and is provided in a manner that establishes a thorough understanding of the present invention. There may be aspects of the present invention that may be practiced without the implementation of some features as they are described. It should be understood that some details have not been described in detail in order to not unnecessarily obscure focus of the invention.

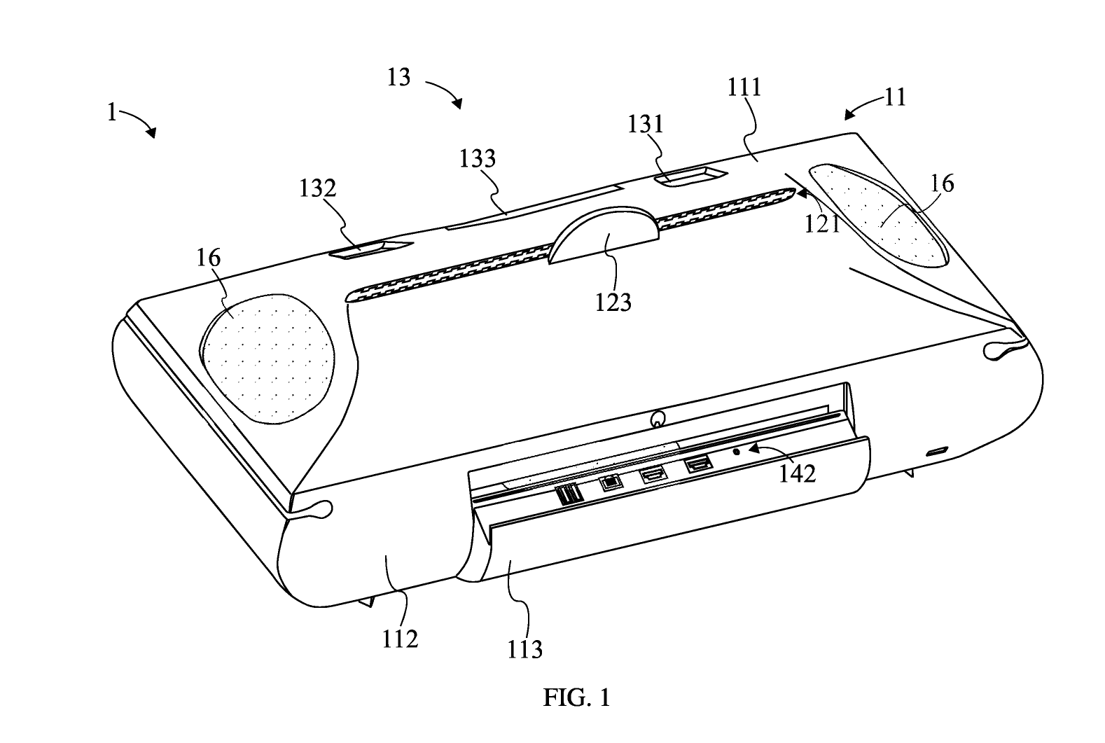

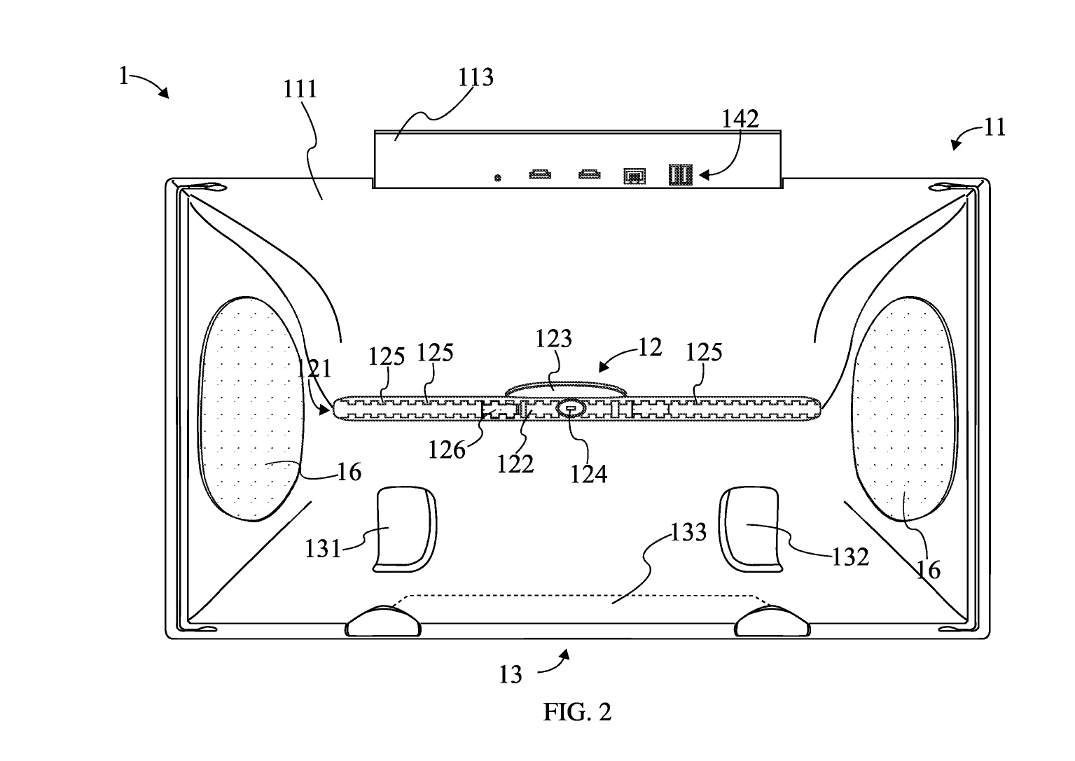

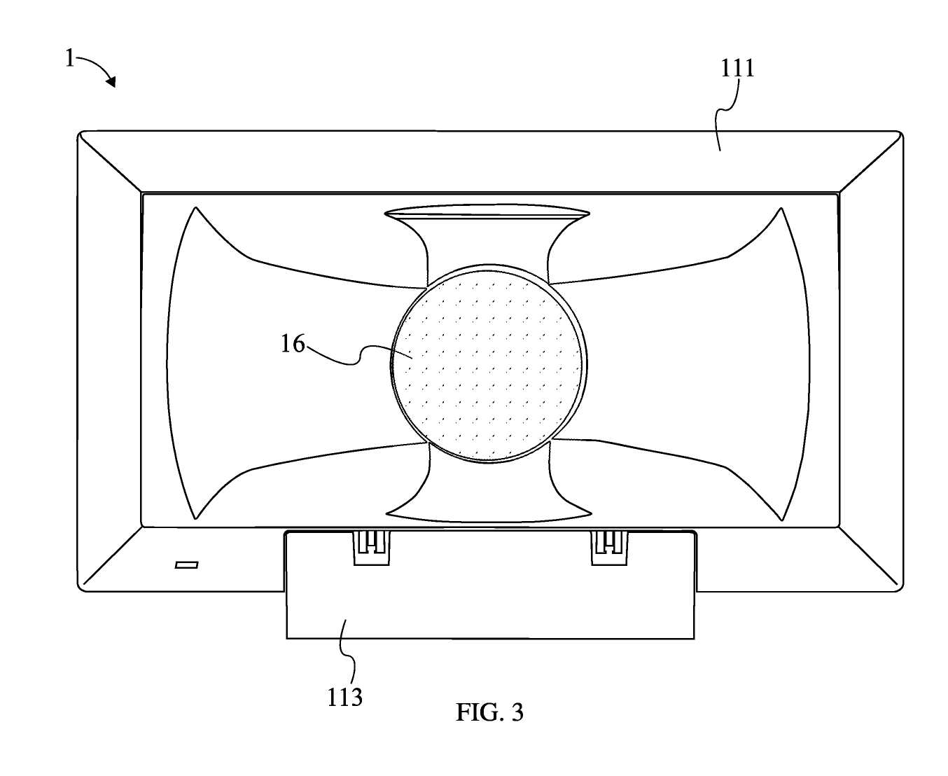

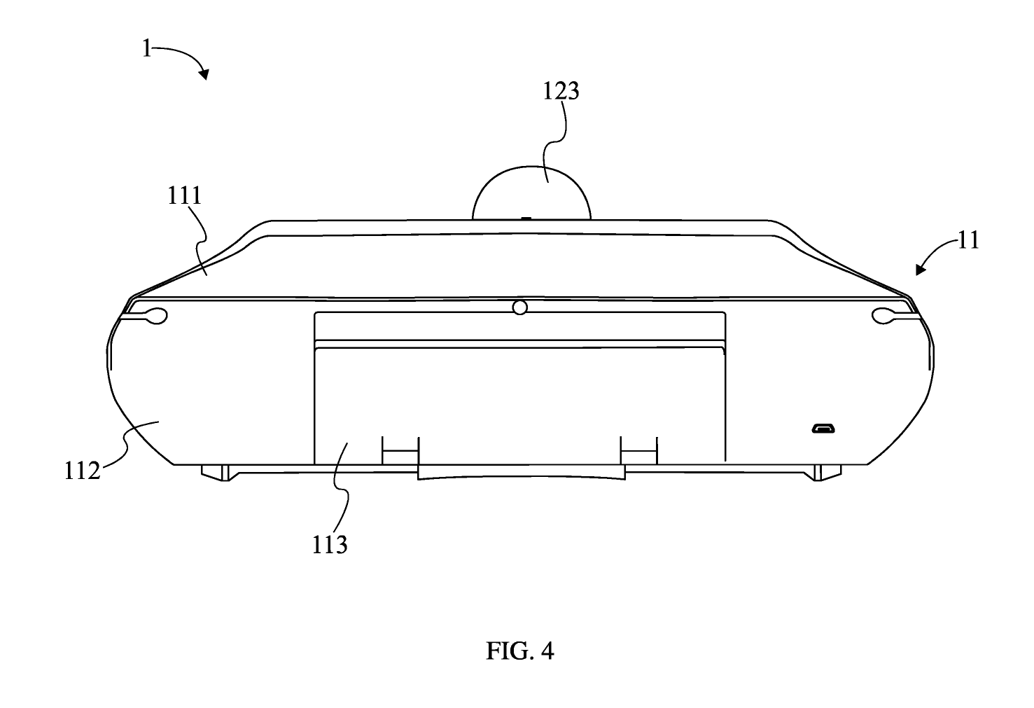

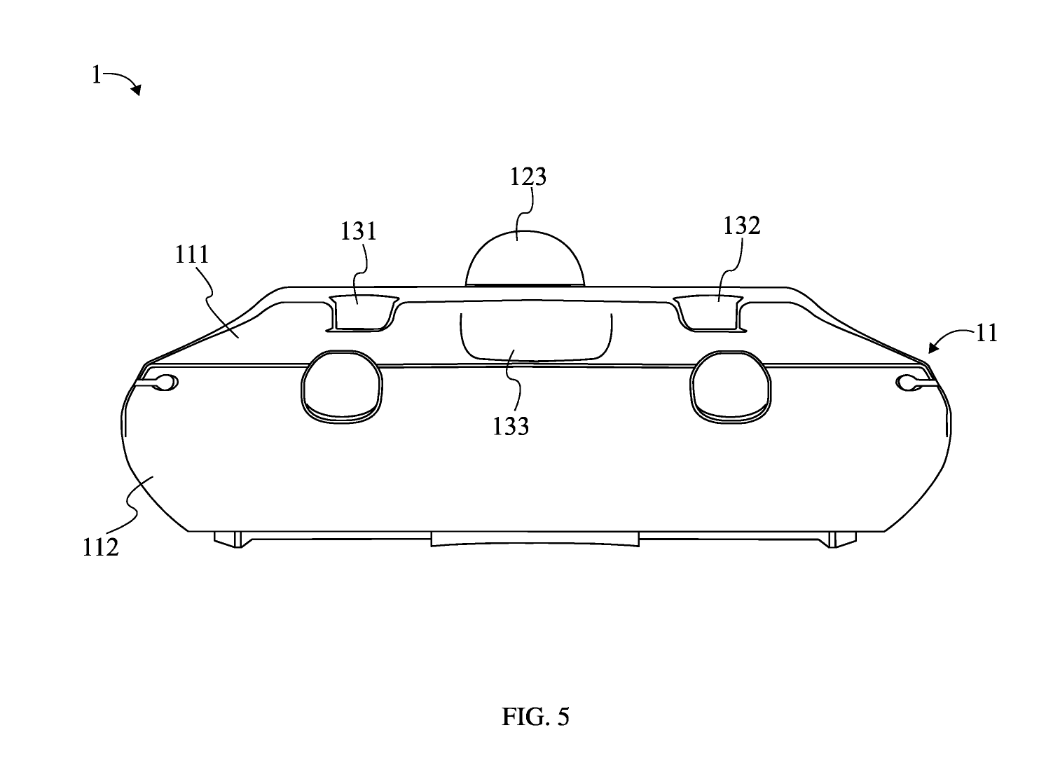

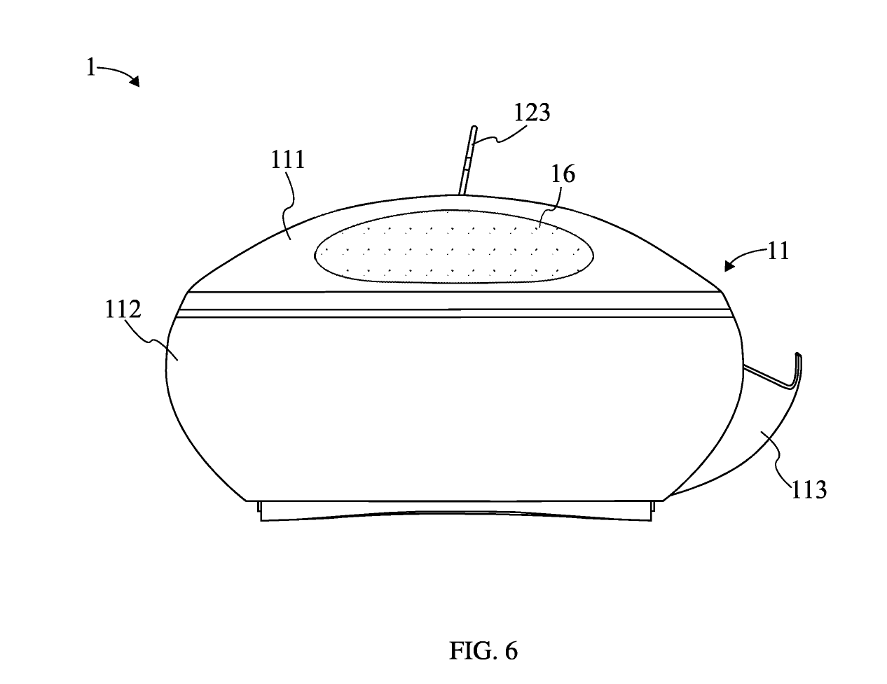

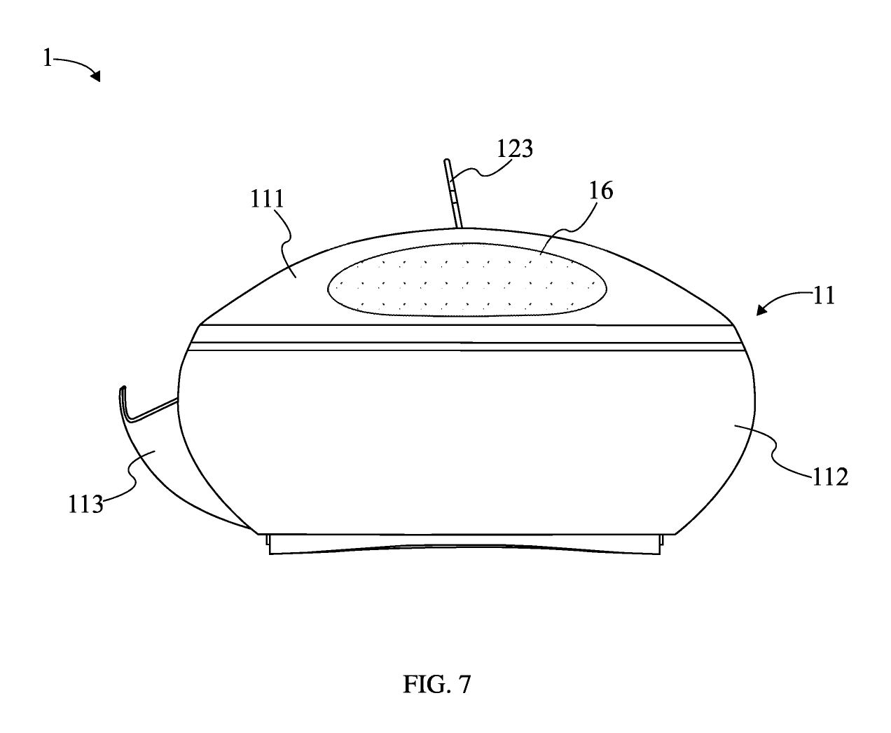

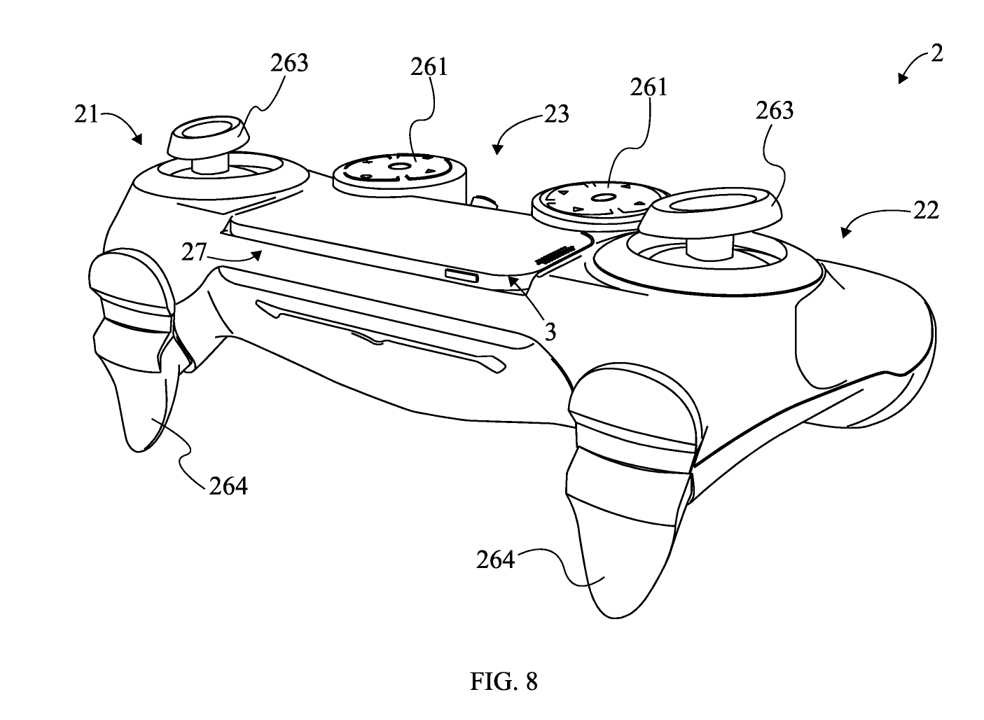

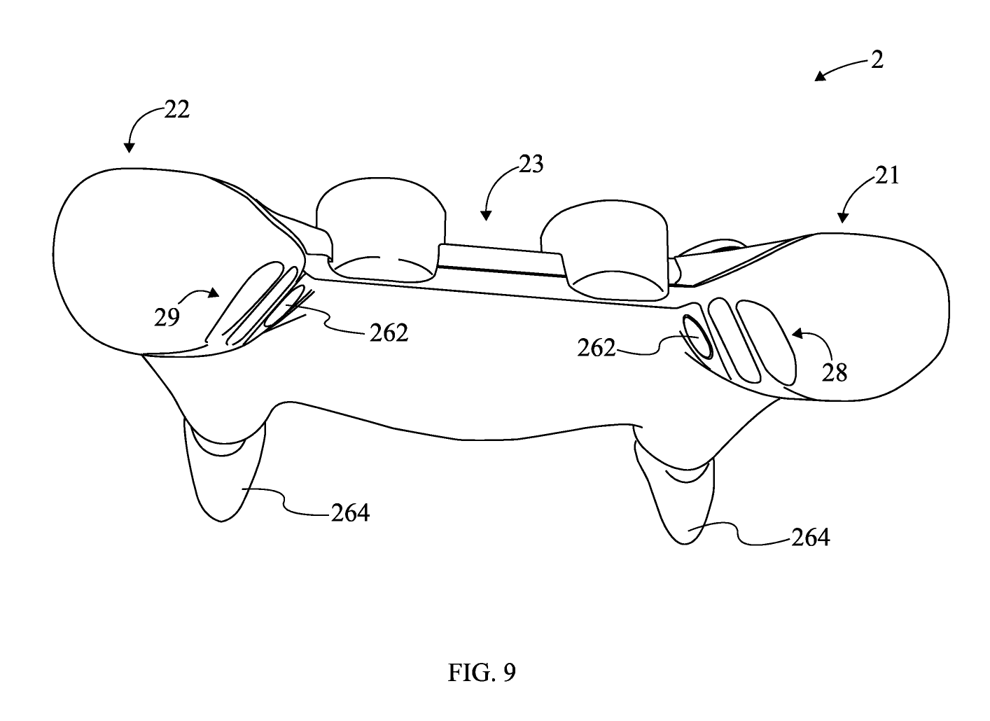

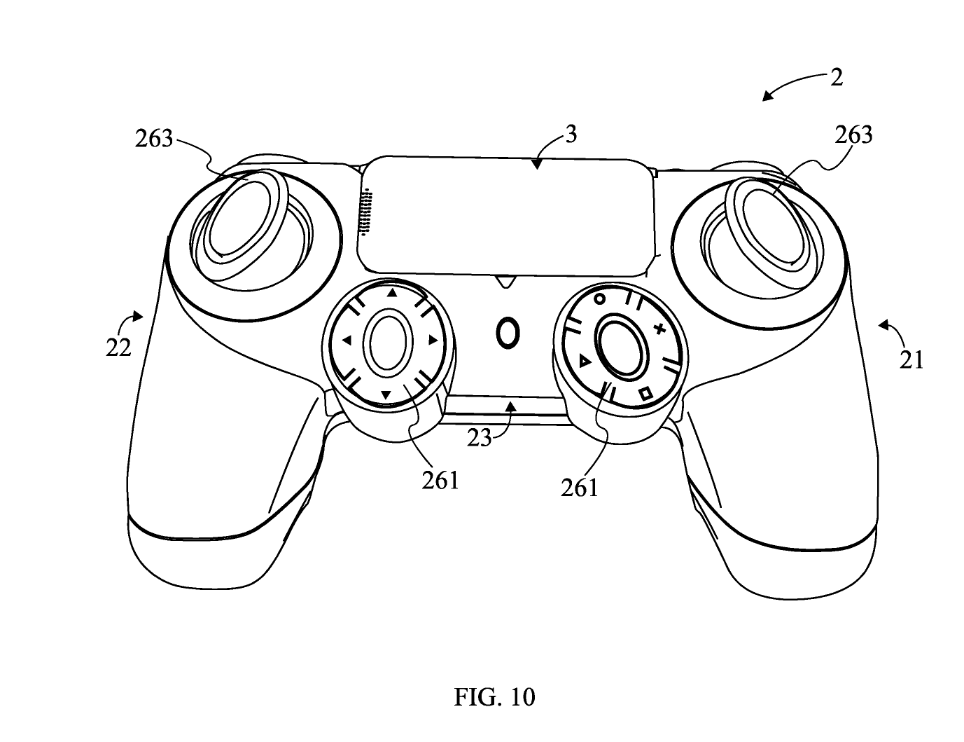

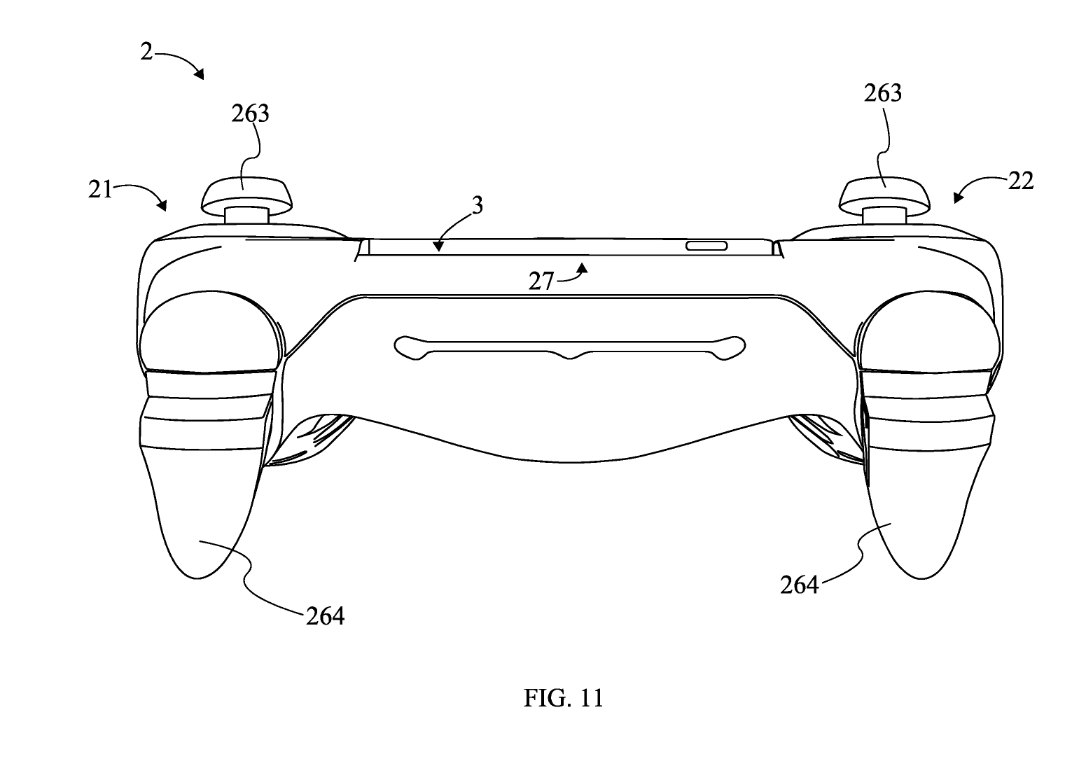

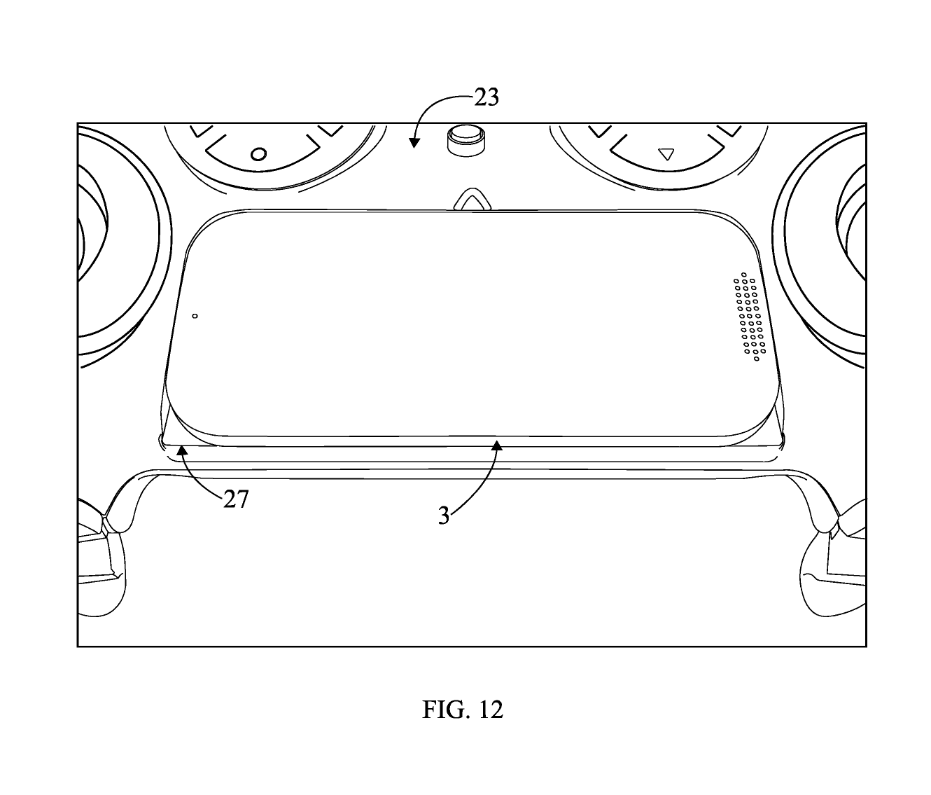

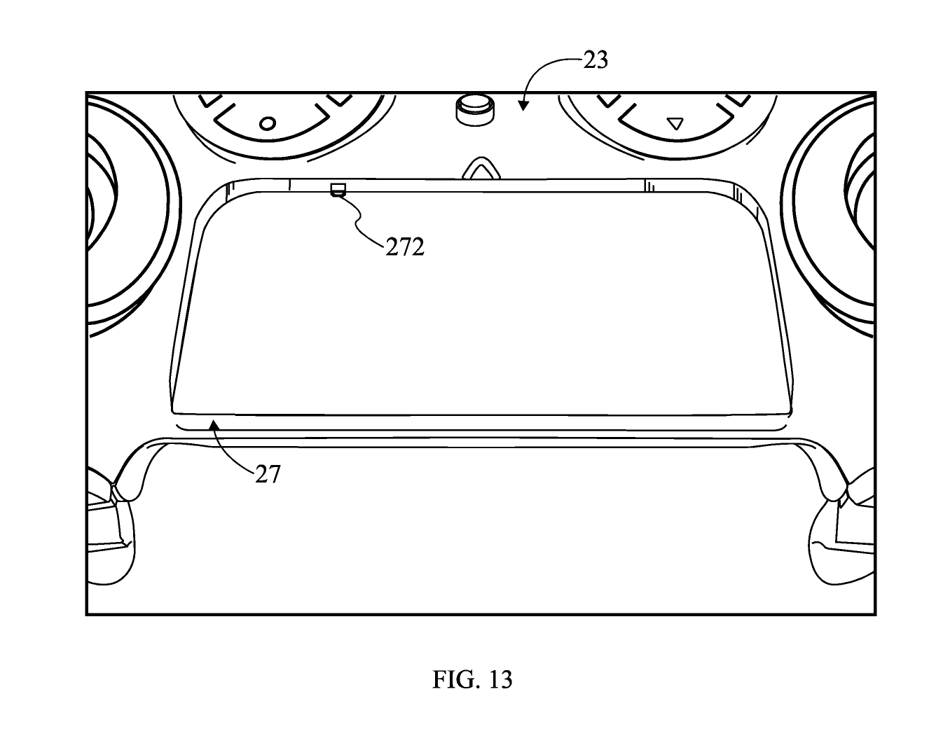

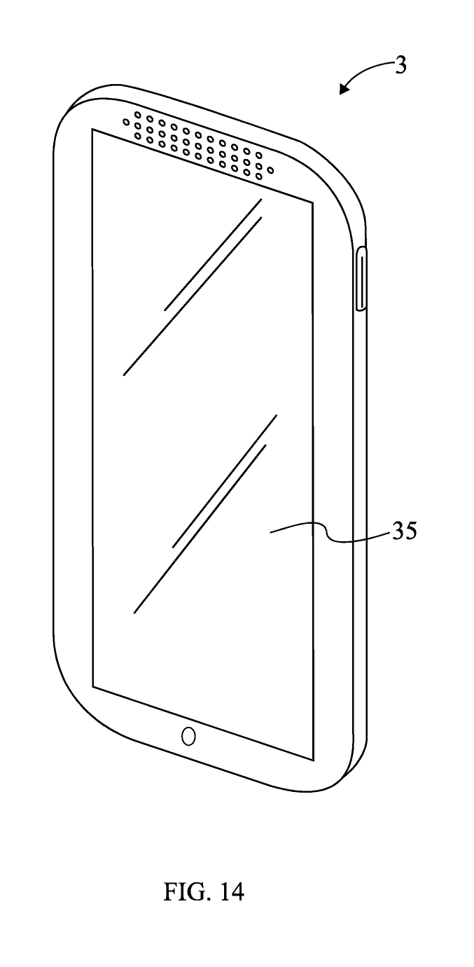

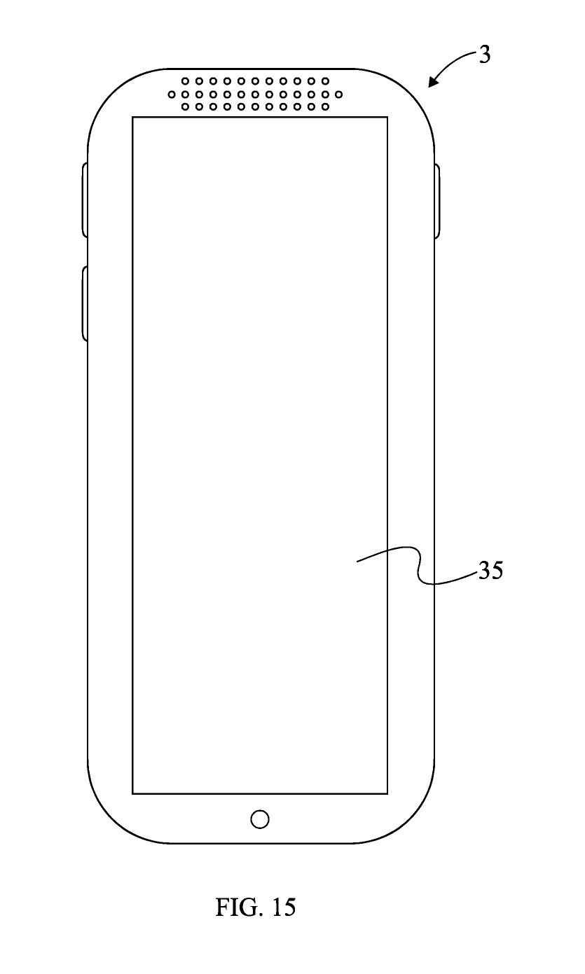

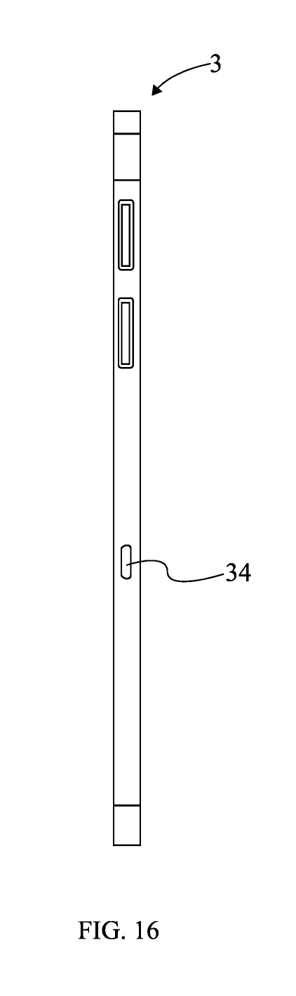

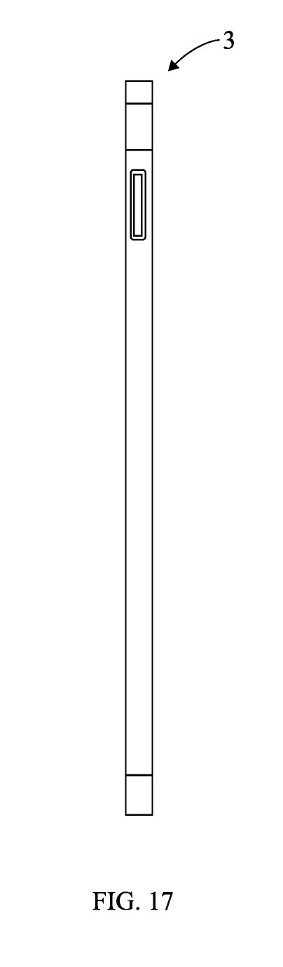

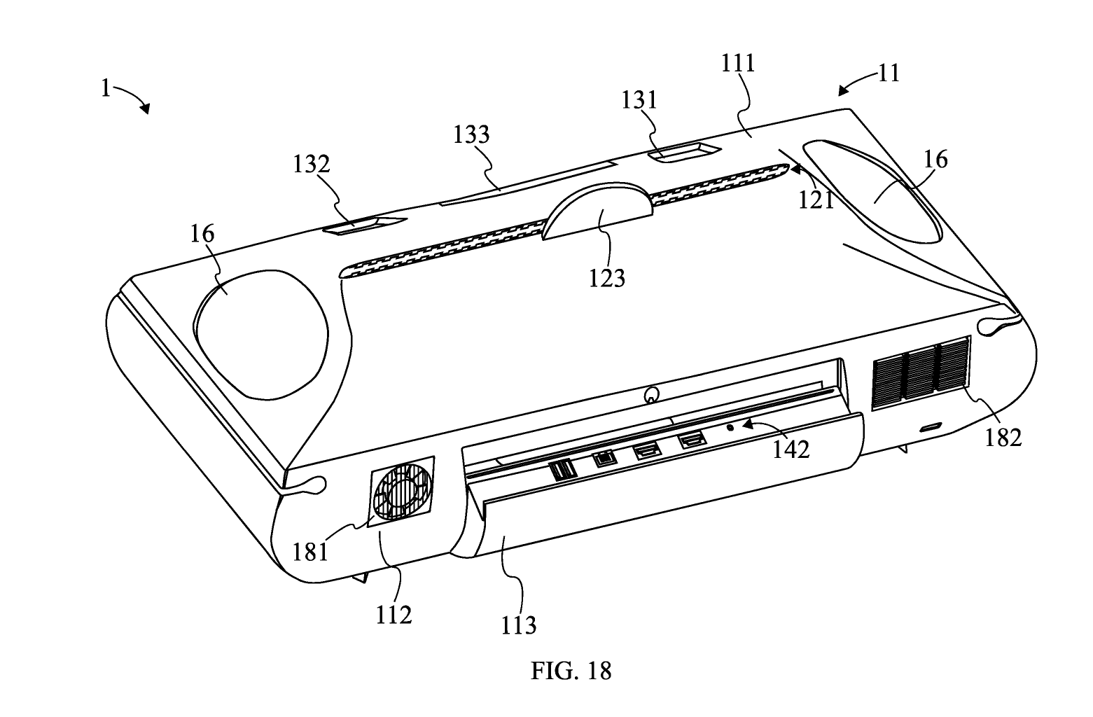

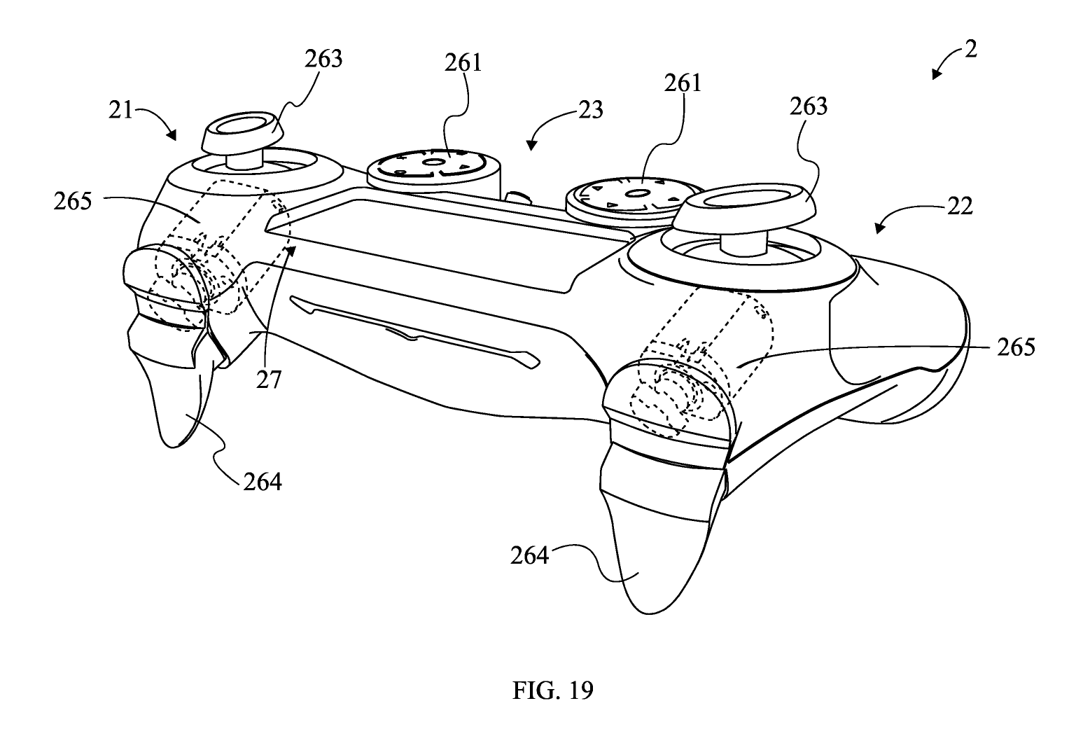

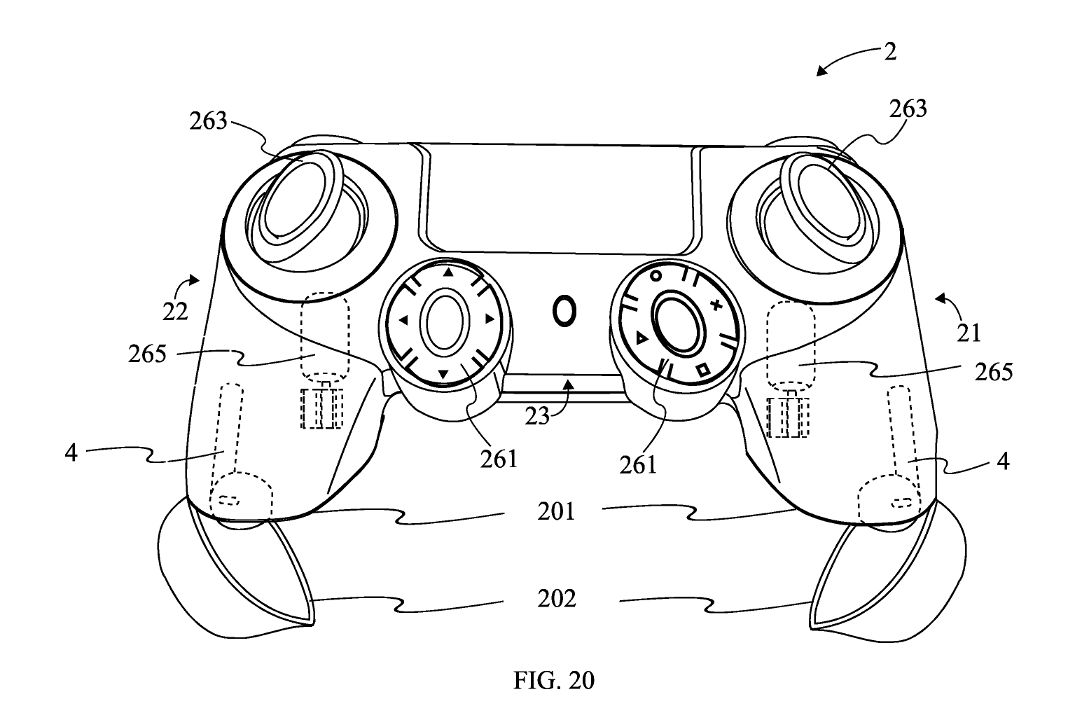

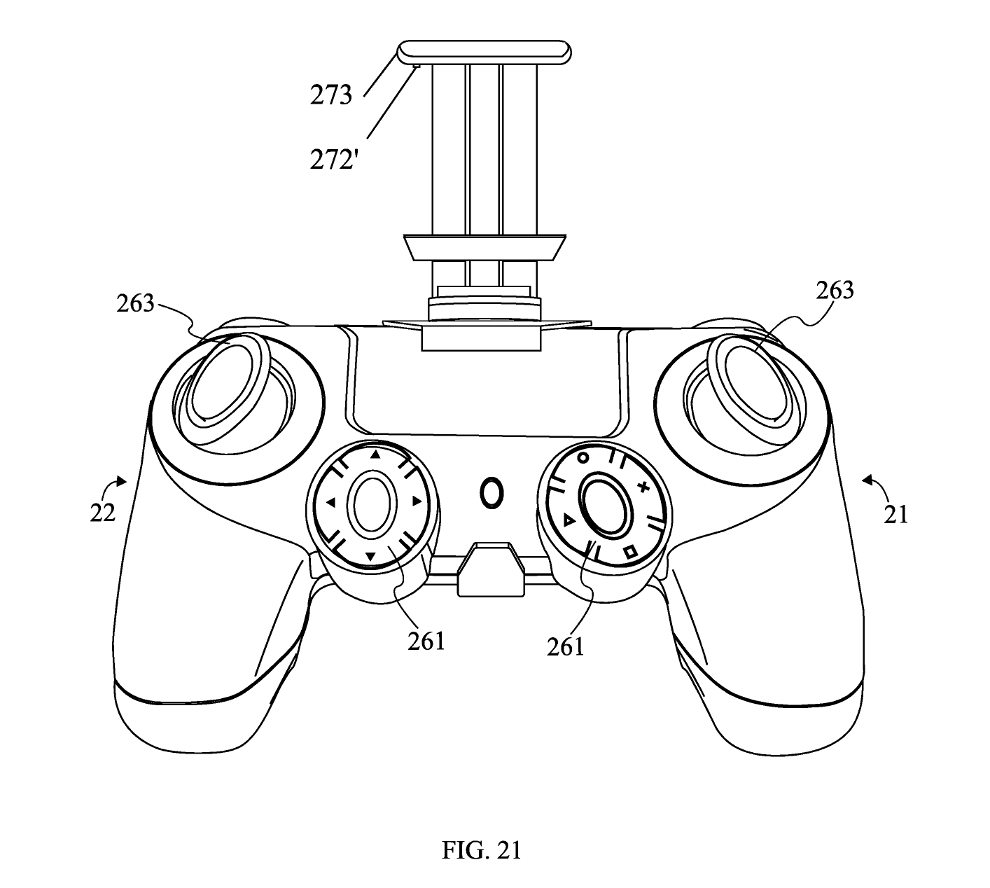

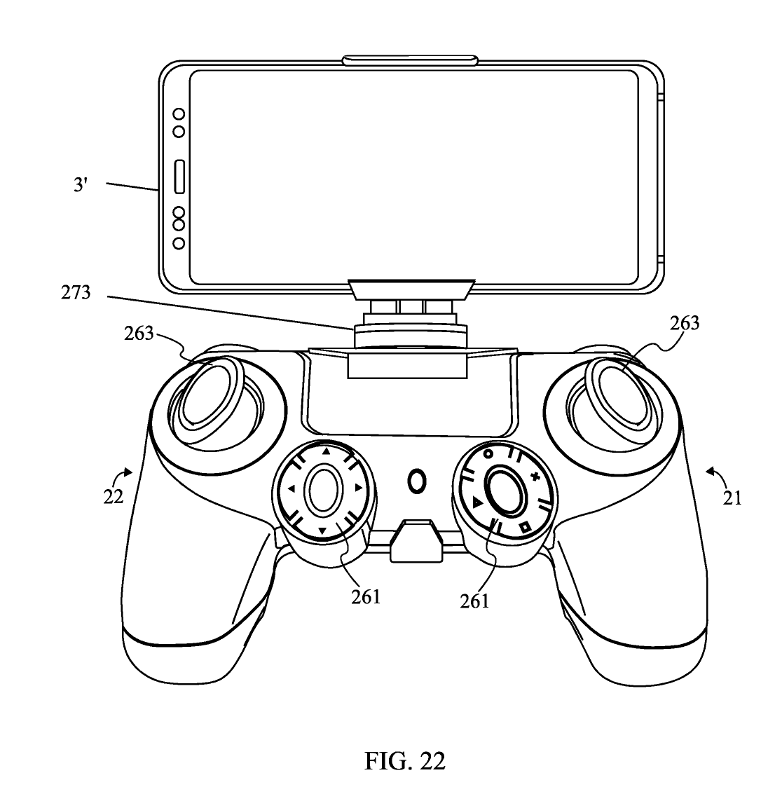

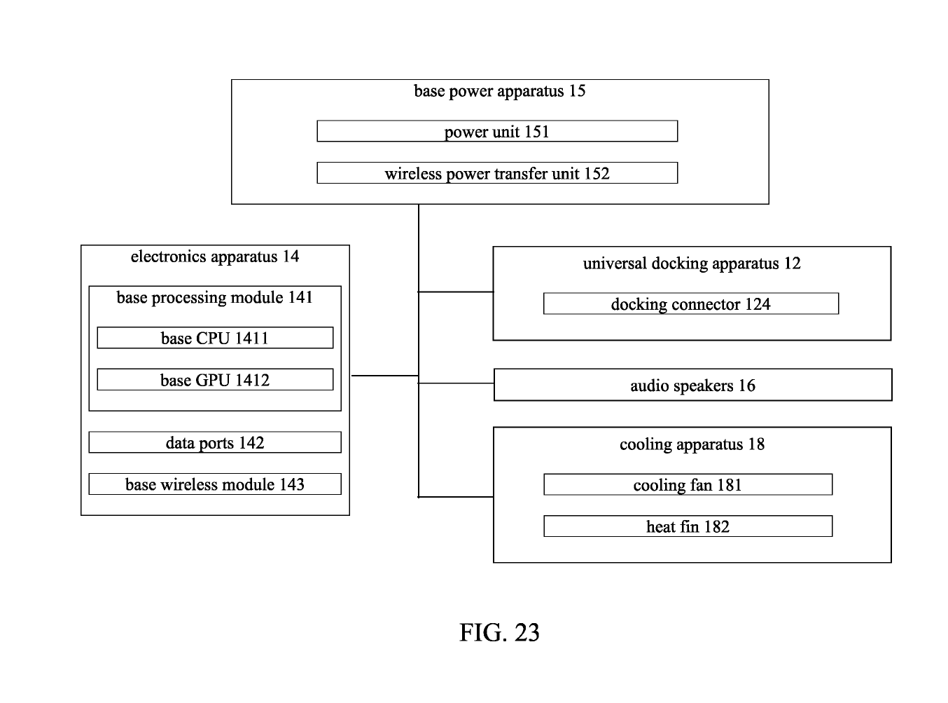

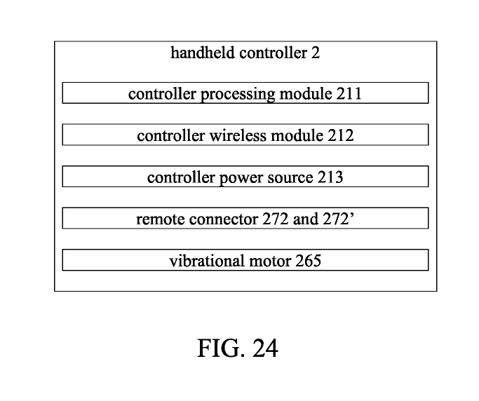

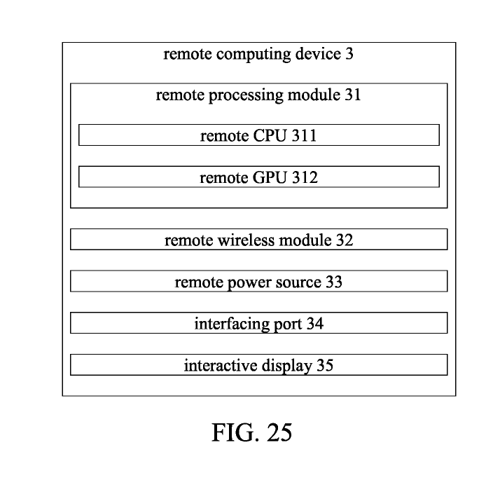

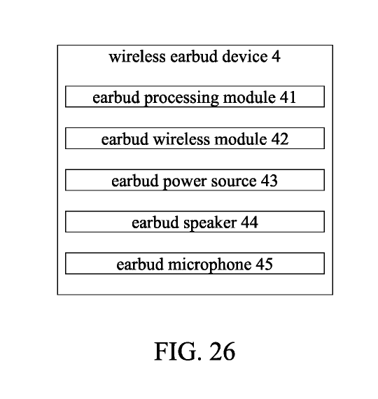

Please refer to FIGS. 1-26, the present invention is a portable entertainment system which interfaces a base unit 1, a handheld controller 2, a remote computing device 3 and a wireless earbud device 4 in order to form a fully functional micro console. The result is a compact and easy to transport system. The created micro console affords users with a wide range of capabilities, some examples of which include but are not limited to playing video games and serving as an audio dock.

The present invention comprises the base unit 1, the handheld controller 2, the remote computing device 3 and the wireless earbud device 4. The base unit 1 serves as a dock for the handheld controller 2, the remote computing device 3 and the wireless earbud device 4. The handheld controller 2 serves as a dock for the remote computing device 3. Further, the base unit 1 provides several capabilities for serving as a micro console, allowing for connections to be made with external power sources, audio-visual equipment, and data systems, as well as networks, such as Bluetooth connections, WiFi networks, cellular networks, or satellite networks.

The base unit 1 comprises a frame 11, a universal docking apparatus 12 with a docking connector 124, a controller dock 13, an electronics apparatus 14, a base power apparatus 15, a plurality of audio speakers 16 and a cooling apparatus 18. The universal docking apparatus 12, which receives the remote computing device 3, is integrated atop the frame 11. It is emphasized that the remote computing device 3 is preferably a “smartphone device”, for example a personal smartphone or tablet. The universal docking apparatus 12 allows for the position of the remote computing device 3 to be adjusted as desired by a user, as necessary according to a computing device 3's connector placement and orientation. By placing the remote computing device 3 in the universal docking apparatus 12, a user is able to use components of the base unit 1 in conjunction with the remote computing device 3. For example, the remote computing device 3 could output music to an audio apparatus of the base unit 1.

The controller dock 13 allows the handheld controller 2 to be secured atop the base unit 1 when not in use, and as such is integrated atop the frame 11. The electronics apparatus 14 and the base power apparatus 15 support computing function of the present invention, as described later, and are housed within the frame 11. The electronics apparatus 14 comprises a base processing module 141, a plurality of data ports 142 and a base wireless module 143. The base processing module 141, the plurality of data ports 142 and the base wireless module 143 are electrically connected with one another. The base processing module 141 comprises a base central processing unit (base CPU) 1411 and a base graphics processing unit (base GPU) 1412. The base CPU 1411 and the base GPU 1412 being electrically connected with each other. The base power apparatus 15 is electrically connected to the universal docking apparatus 12, the electronics apparatus 14, the plurality of audio speakers 16 and the cooling apparatus 18. This allows for power to be supplied to electricity-dependent components as needed.

The handheld controller 2 comprises a first grip 21, a second grip 22, a central console 23, a first plurality of inputs 24, a second plurality of inputs 25 and a remote device dock 27. The first grip 21 and second grip 22 allow a person to grasp the handheld controller 2, and thus are connected on either side of the central console 23. The first plurality of inputs 24 and the second plurality of inputs 25 are placed on the central console 23, where they can easily be accessed by a user's fingers (most commonly the thumb) without requiring a user to release the first grip 21 or second grip 22. The remote device dock 27, which allows for the remote computing device 3 to be directly interfaced with the handheld controller 2, is integrated into the central console 23.

As thus far described, the present invention provides an entertainment system which is created from the base unit 1, the handheld controller 2, the remote computing device 3 and the wireless earbud device 4. Different functionalities are afforded to a user by docking the remote computing device 3 to the base unit 1 or to the handheld controller 2. Each of these components, along with subcomponents, are subsequently described in more detail.

Regarding the universal docking apparatus 12, the frame 11 comprises a supporting top surface 111 while the universal docking apparatus 12 comprises a track 121, a carriage 122, a cradle 123 and the docking connector 124. The track 121 is positioned along the top surface 111 of the frame 11, preferably in a straight line adjacent to an upper edge of the frame 11. The track 121 receives a carriage 122, which is slidably engaged with the track 121. This allows for linear movement of the carriage 122 along the track 121. The cradle 123 is mounted to the top surface 111, while the docking connector 124 is adjacently connected to the carriage 122. The carriage 122 is provided to receive the remote computing device 3, while data and power can be transferred between the base unit 1 (specifically the electronics apparatus 14 and base power apparatus 15) and the remote computing device 3. Positional adjustments are possible thanks to the carriage 122 being slidably and rotatably engaged along the track 121. As a result, a user is always able to rotate their docked remote computing device 3 (e.g. smartphone or tablet) to face the front of the console, regardless of the orientation of a specific connector thereof. The cradle 123 can then serve as a backrest for any docked smart mobile device. In short, when the remote computing device 3 is coupled to the universal docking apparatus 12, a user is able to move and rotate the remote computing device 3 to a desired position and orientation.

In order to lock the carriage 122 in a desired position, the universal docking apparatus 12 further comprises a plurality of stops 125 and a spring latch 126. The plurality of stops 125 is evenly distributed along the track 121 while the spring latch 126 is adjacently connected to the carriage 122. In an equilibrium position, the spring latch 126 is pushed upwards, such that it is secured via one of the plurality of stops 125. Effectively, the carriage 122 cannot move because the spring latch 126 is blocked by the plurality of stops 125. A user can enable movement of the carriage 122 by pressing down on the spring latch 126, which disengaged the spring latch 126 from the plurality of stops 125 and allows for the carriage 122 to be moved along the track 121 to a new desired position.

While the above describes the docking apparatus of the preferred embodiment, alternative implementations remain possible within the scope of the present invention. For example, the spring latch 126 and the plurality of stops 125 could potentially be replaced by a set screw that is placed in the carriage 122. Tightening or loosening of the set screw would then allow or prevent movement of the carriage 122 along the track 121. Another possibility is removal of the track 121 and the carriage 122, instead opting for a fixed docking solution, though this reduces the versatility of the present invention. Other solutions not described remain possible as long as the universal docking apparatus 12 is able to physically receive the remote computing device 3 and enable electrical and communicable connections between the remote computing device 3 and sub components of the base unit 1.

The controller dock 13, which supports the handheld controller 2, comprises a first indent 131, a second indent 132 and a central indent 133. The first indent 131, the second indent 132 and the central indent 133 are contoured to match a first trigger 264, a second trigger 264, and the central console 23 of the handheld controller 2. Each of the first indent 131, the second indent 132 and the central indent 133 is positioned into the top surface 111 of the frame 11, creating a cavity that fits the corresponding component of the handheld controller 2. More specifically, the central indent 133 is shaped to receive the main body of the handheld controller 2 (e.g. the central console 23). This central indent 133 is positioned between the first indent 131 and the second indent 132, which are shaped to receive the first grip 21 and the second grip 22, respectively. It is noted that the alterations are possible to the controller dock 13. For example, a single indent could be positioned along the top surface 111, with the two grips and main body of the handheld controller 2 sharing the single cavity. While such alternative options exist, the first indent 131, the second indent 132, and the central indent 133 are preferred due to providing a more secure docking solution for the handheld controller 2.

To provide a user with access to the electronics apparatus 14, and more specifically the plurality of data ports 142, the frame 11 comprises a lateral surface 112 and a panel 113. The panel 113 is a door which is hingedly connected to the lateral surface 112, with the axis of rotation being positioned adjacent to a base of the frame 11. The plurality of data ports 142 are mounted to an interior of the panel 113; as a result, when the panel 113 is closed, the plurality of data ports 142 are hidden within the frame 11. This helps create a more aesthetically appealing and cleaner appearance for the base unit 1 when the plurality of data ports 142 are not in use.

Preferably, to help open the panel 113 to access the plurality of data ports 142, a groove is positioned into the lateral surface 112 adjacent to a top of the panel 113. This groove allows a user to place their finger beneath an interior face of the panel 113. This makes it easier for a user to pull on the panel 113 without adding external elements, such as a tab, that might detract from the aesthetics of the present invention.

To hold the panel 113 in an open position, a ratchet apparatus is provided, such that the panel 113 can be held in different states (for example closed, partially open, or fully open) without requiring a user to actively hold the panel 113. Addressing the plurality of data ports 142, the present invention preferably includes a universal serial bus (USB) port, a 3.5 mm audio jack, a High-Definition Multimedia Interface (HDMI), and an Ethernet port. It is also preferable to provide an HDMI connector which employs screencasting, enabling peer-to-peer connections of standard wireless networks. An example standard for such HDMI-Display connections is Miracast. However, different ports and standards are compatible with the present invention. For example, the USB port could be Type B or Type C. Further, the connector could be of the micro, mini, or “standard” size. Examples of further potential ports include display port and a Secure Digital (SD) card slot.

The plurality of data ports 142 can be enabled through various standards, the most common of which are the Mobile High-definition Link (MHL) standard and the SlimPort standard. The use of MHL and SlimPort standards is advantageous as it simplifies construction of the present invention. Rather than having to individually configure each connection, an internal adapter for each standard (i.e. one MHL adapter and one SlimPort adapter) can be installed within the base unit 1. This improves compatibility of the present invention, as devices that utilize either of the standards can be interfaced with the present invention. Additionally, the MHL and SlimPort adapters allow for docked devices to be recharged.

In the preferred embodiment of the present invention, it is preferable for mirror-imaging capabilities to be provided via the MHL standard link connection. This serves as an audio-visual interface that allows consumers to connect mobile phones, tablets, or other smart devices to high-definition displays and audio receivers.

While the preferred embodiment includes the panel 113 for keeping the plurality of data ports 142 hidden when not in use, other embodiments may omit the panel 113. For these embodiments, the plurality of data ports 142 are positioned directly into the lateral surface 112 of the frame 11. Other configurations of the plurality of data ports 142 relative to the frame 11 are possible as long as the plurality of data ports 142 retain their connection to the base processing module 141 and the base power apparatus 15.

Preferably, the electronics apparatus 14 comprises the base wireless module 143. This base wireless module 143 enables wireless communications with proximal devices. The base processing module 141, the plurality of data ports 142 and the base wireless module 143 are electronically connected to one another, allowing the base wireless module 143 to transmit data from said components. The base processing module 141, the plurality of data ports 142 and the base wireless module 143 are powered via an electrical connection with the base power apparatus 15. Ideally, the base wireless module 143 is implemented as a Bluetooth connection. Potentially, said Bluetooth connection could be augmented by or replaced by other standards, such as WiFi networks.

To allow the base unit 1 to serve as a multimedia dock, it preferably comprises the plurality of audio speakers 16. The plurality of audio speakers 16 are mounted into the frame 11, allowing for audio content received from the base processing module 141 to be output in proximity of the base unit 1. The number of the plurality of audio speakers 16 can be varied in different embodiments of the present invention. For example, in the preferred embodiment, two audio speakers 16 are positioned at either side of the top surface 111, while a bass speaker 16 is positioned at a bottom portion of the frame 11. Preferably, the bottom portion is slightly elevated from a supporting surface (for example by small supports) to help provide better acoustics from the bass speaker 16. Docked devices, such as the remote computing device 3, can thus make use of the plurality of audio speakers 16 and other electronic connections of the base unit 1.

The base power apparatus 15 comprises a power unit 151 and a wireless power transfer unit 152. The power unit 151 can be a battery (effectively an internal power source) or an adapter for a wall socket connection (effectively an external power source). Potentially, both options could be provided to allow the present invention to operate via battery power normally, but be plugged into a wall socket when available or needed to recharge the battery. The wireless power transfer unit 152 is housed in the frame 11, next to the controller dock 13. This wireless power transfer unit 152 is thus able to recharge the handheld controller 2, the remote computing device 3 and the wireless earbud device 4, without requiring direct electrical connections. The wireless power transfer unit 152 simultaneously charges the handheld controller 2 and the remote computing device 3 and the wireless earbud device 4 when the handheld controller 2, the remote computing device 3 and the wireless earbud device 4 each is wirelessly coupled with the base unit 1. The exact method of wireless power transfer is not restricted by the present invention; as an example, inductive charging could be used, but others are equally suitable. The primary concerns with the wireless charging method will be cost, availability, and lifespan.

Moving on to describe the handheld controller 2 in more detail, the remote device dock 27 comprise a recess 271 and a remote connector 272. The recess 271 is a planar depression formed in the central cavity, into which the remote computing device 3 can easily be inserted. The remote connector 272 plugs into the remote computing device 3, allowing for communications between the handheld controller 2 and the remote computing device 3. The remote device dock 27 allows the remote computing device 3 to be positioned flush with the handheld controller 2. Effectively, the remote computing device 3 serves as a screen for the handheld controller 2. The result is similar to existing handheld gaming consoles, though they lack the adaptability of the present invention, i.e., especially the base graphics processing unit 1412.

The first plurality of inputs 24 and the second plurality of inputs 25 are provided for the first grip 21 and the second grip 22, respectively. As such, the first plurality of inputs 24 are mounted to the first grip 21 while the second plurality of inputs 25 are mounted to the second grip 22. Each of the first plurality of inputs 24 and the second plurality of inputs 25 provides several input mechanisms, examples of specific input mechanisms and locations being described in more detail later. Providing multiple inputs allows a user to simultaneously use both hands, as well as multiple digits of each hand, to operate the handheld controller 2.

The handheld controller 2 serves as a primary interface for a user and, when used in combination with the remote computing device 3, essentially acts as a handheld entertainment console. To facilitate this, there are a number of components and configurations which are preferably implemented with the handheld controller 2. Resultantly, the handheld controller 2 preferably comprises a first plurality of ergonomic finger grooves 28 and a second plurality of ergonomic finger grooves 29. The first plurality of ergonomic finger grooves 28 are positioned into a base surface of the first grip 21. Similarly, the second plurality of ergonomic finger grooves 29 are positioned into a base surface of the second grip 22. These first plurality of ergonomic finger grooves 28 and the second plurality of ergonomic finger grooves 29 are formed at a bottom of the handheld controller 2 and are contoured to receive a person's fingers. The first plurality of ergonomic finger grooves 28 and the second plurality of ergonomic finger grooves 29 make the handheld controller 2 more comfortable to grasp, especially over extended periods of time. This ultimately improves user comfort and helps create a positive experience with regards to the present invention.

Further, the first plurality of ergonomic finger grooves 28 and the second plurality of ergonomic finger grooves 29 can be used to provide additional inputs for the handheld controller 2. Thus, the first plurality of inputs 24 and the second plurality of inputs 25 each comprise an auxiliary button 262. This auxiliary button 262 is mounted into one of the finger grooves on the bottom of the handheld controller 2, with at least one button being provided for each plurality of finger grooves. Thus, the auxiliary button 262 of the first plurality of inputs 24 is mounted into one of the first plurality of ergonomic finger grooves 28 of the first grip 21, while the auxiliary button 262 of the second plurality of inputs 25 is mounted into one of the second plurality of ergonomic finger grooves 29 of the second grip 22.

To provide multi-axis input capabilities, the first plurality of inputs 24 and the second plurality of inputs 25 each comprise an analog stick 263. Each analog stick 263 (i.e. one from the first plurality of inputs 24 and one from the second plurality of inputs 25) is pivotally mounted to the handheld controller 2. More specifically, one analog stick 263 is mounted to the first grip 21, next to the central console 23, while another analog stick 263 is mounted to the second grip 22, on the other side of the central console 23. This pivotal connection allows for the analog sticks 263 to be used to provide input along two axes, useful for providing directional input for motion in video games. Further, to improve ergonomics of the analog sticks 263, each analog stick 263 preferably comprises a head and an indent. The indent is positioned into the head, forming an oval shaped groove which comfortably receives a user's fingertip.

Potentially, the first plurality of inputs 24 and the second plurality of inputs 25 each comprise the trigger 264. Each trigger 264 is laterally mounted into its corresponding grip. Thus, one trigger 264 is mounted into the first grip 21 and another trigger 264 is mounted into the second grip 22. Preferably, the triggers 264 are curved so that a user can slide their finger along each trigger 264 to provide a finer level of control, especially as compared to an alternative straight trigger 264. A further benefit derived from the configuration of the present invention is the reverse triggering implementation. That is, the contours of the triggers 264 allow a user to easily access upper triggers (colloquially referred to as L-1 and R-1, short for left-1 and right-1) by sliding their fingers upwards from the lower triggers (colloquially referred to as L-2 and R-2, short for left 2 and right 2).

Too, it is possible for the first plurality of inputs 24 and the second plurality of inputs 25 to each comprise a plurality of buttons 261. Each of the plurality of buttons 261 is configured in a circular pattern, allowing a user's finger to easily switch between different buttons. Positioned between the plurality of buttons 261 is a finger indent, where a user can rest their finger when not actively engaging one of the plurality of buttons 261. Each of the plurality of buttons 261 is positioned flat on the handheld controller 2, with the slight curvature towards the finger indent (which serves as a thumb rest center position). As with other inputs described to this point, two separate groups of buttons, with one plurality of buttons 261 being mounted to the first grip 21 and another plurality of buttons 261 being mounted to the second grip 22.

Overall, the plurality of inputs provides a user with multiple options for interacting with the handheld controller 2. For example, one finger could be pressing a trigger 264 while another finger could be manipulating a trigger 264, pressing a button, or otherwise interacting with the handheld controller 2. It is noted that different configurations and combinations of inputs remain possible within the scope of the present invention. The primary purpose of the plurality of inputs is to enable a user to interact with a docked remote computing device 3 by means of the handheld controller 2.

The remote computing device 3 acts as one of the brains of the present invention; the base unit 1 acts as the other brain of the present invention; any electronic device can be utilized for this purpose by installing a software application. The software application allows the remote computing device 3 to directly interact with the base unit 1 and the handheld controller 2. Resultantly, the present invention can be used to play video games, manage multimedia content, or perform further functions as desired by a user.

Preferably, the remote computing device 3 comprise a remote processing module 31, a remote wireless module 32, a remote power source 33, an interfacing port 34 and an interactive display 35. The remote processing module 31, the remote wireless module 32, the remote power source 33, the interfacing port 34 and the interactive display 35 are electrically connected with one another. The remote processing module 31 comprise a remote central processing unit (remote CPU) 311 and a remote graphics processing unit (remote GPU) 312. The remote CPU 311 and the remote GPU 312 being electrically connected with each other. The remote processing module 31 allows the remote computing device 3 to run software applications which are output to the interactive display 35. The remote wireless module 32 allows for the remote computing device 3 to communicate with other electronic devices without having a direct physical connection. This allows, for example, the remote computing device 3 to use the base unit 1 (by means of the base wireless module 143) as an access point via a wireless local area network connection, such as WiFi networks, or a Bluetooth connection. The remote power source 33 provides the energy necessary for operation of the remote processing module 31, the remote wireless module 32, the interfacing port 34 and the interactive display 35. Further, the remote power source 33 can be recharged when coupled, thanks to the electrical connection with the interfacing port 34, or to the wireless communication between the remote wireless module 32 and the wireless power transfer unit 152.

The remote computing device 3 can be docked into either the base unit 1 or the handheld controller 2, by means of the universal docking apparatus 12 or the remote device dock 27 as earlier described. For example, the remote computing device 3 can be coupled with the base unit 1 through the universal docking apparatus 12, with the interfacing port 34 of the remote computing device 3 receiving the docking connector 124 of the universal docking apparatus 12. Alternatively, the remote computing device 3 can directly dock with the handheld controller 2 by means of the remote device dock 27. In this example, the interfacing port 34 of the remote computing device 3 receives the remote connector 272 of the handheld controller 2, allowing the two to be used together as a handheld console.

Additional components which are desirable for the present invention include an illuminated strip (“lighting connection array”) which is positioned around part of the base unit 1 and the handheld controller 2. These illuminated strips can be configured to light up when the corresponding component is in use. Alternatively, the illuminated strips could be configured to remain lit at all times, or allow a user to switch them on or off. Other preferred features are the provisional of interface controls for the base unit 1, handheld controller 2, and remote computing device 3. More specifically, a power button is ideally provided for each unit to facilitate turning the respective unit off or on. Further, the remote computing device 3 preferable has volume controls, placed on the side of the unit where a user can access them even when docked into the handheld controller 2. The remote computing device 3 also has a microphone that allows for audio input (e.g. speaking) to be received from a user and (for example) transmitted to another device or person.

Resulting from the configuration of components, the present invention offers several benefits over existing solutions. Most notably, the present invention is not merely a docking station, but instead provides a combination of multimedia (e.g. audio played from the speakers) output capabilities, offers media connections (e.g. the 3.5 mm jack and the HDMI port), and serves as an access point (via the Ethernet port and wireless modules), all of which are made available to a docked or otherwise coupled mobile computing device. Further, by providing both MHL adapters, the present invention supports outputting of audio-visual data. In addition, these adaptors enable mirror imaging, allowing multimedia output from the mobile computing device to be displayed to a television or other electronic device. The mobile computing device, when installed with the appropriate software, is able to control features of both the base unit 1 and the handheld controller 2. For example, the application can be used to control haptic feedback intensity, the mapping of buttons on the controller, default Bluetooth devices to pair with, and so on. Thanks to attention to ergonomics (e.g. the finger grooves of the handheld controller 2), the result is a multipurpose and user friendly electronic apparatus with a wide range of applications.

Besides, the handheld controller 2 further comprises a controller processing module 211, a controller wireless module 212 and a controller power source 213. The controller processing module 211, the controller wireless module 212 and the controller power source 213 are electrically connected with one another. The controller wireless module 212 is wirelessly coupled with the base wireless module 143 and/or the remote wireless module 32, such that the controller processing module 211 could process data transferred from and/or to the base processing module 141 and/or remote processing module 31. The controller power source 213 provides the energy necessary for operation of the controller processing module 211 and the controller wireless module 212. Further, the controller power source 213 can be wirelessly recharged when the handheld controller 2 is coupled with the base unit 1, thanks to the wireless communication between the controller wireless module 212 and the wireless power transfer unit 152.

Additionally, when the remote computing device 3 is docked to the base unit 1, the remote processing module 31 is electrically connected with the base processing module 141 via the interfacing port 34 and the docking connector 124, such that data can be transferred between the remote CPU 311 and the base CPU 1411. Alternatively, the remote processing module 31 could be wirelessly coupled with the base processing module 141 via the remote wireless module 31 and the base wireless module 143. Meanwhile, the remote GPU 312 is inactive, and the base GPU 1412 is active. In other words, the base GPU 1412 becomes a master GPU of the portable entertainment system. By doing so, the GPU load could be entirely tackled by the base GPU 1412 instead of the remote GPU 312, thereby relieving all geometrical processing (GPU load) from the remote computing device 3 to the base unit 1 when the remote computing device 3 is coupled with the base unit 1 by the interfacing port of the remote computing device 3 being engaged with the docking connector 124 of the universal docking apparatus 12 of the base unit 1 oy by the remote wireless module 31 and the base wireless module 143 being wirelessly coupled with each other.

Furthermore, in order to dramatically dissipate heat generated during operation of the components of the base unit 1 and/or the remote computing device 3, the base unit 1 comprises the cooling apparatus 18. The cooling apparatus 18 comprises a cooling fan 181 and a heat fin 182. The cooling fan 181 and the heat fin 182 are mounted to the lateral surface 112 of the frame 11. Alternatively, the cooling fan 181 and the heat fin 182 could be mounted to any surface of the frame 11, such as the top surface 111 or the bottom surface of the frame 11.

The portable entertainment system further comprises at least one auxiliary handheld controller which is identical to the handheld controller 2. Accordingly, at least two users could use the handheld controller 2 and the at least one auxiliary handheld controller at the same time during operation of the portable entertainment system; alternatively, a single user could selectively use one of the handheld controller 2 and the at least one auxiliary handheld controller. For example, when the handheld controller 2 is running out of power, the single user could use the at least one auxiliary handheld controller while charging the handheld controller 2 via the base 1.

Regarding the wireless earbud device 4, it has two earbuds which are wearable by a user on an ear. The earbuds of the wireless earbud device 4 each comprises an earbud processing module 41, an earbud wireless module 42, an earbud power source 43, an earbud speaker 44 and an earbud microphone 45. The earbud processing module 41, the earbud wireless module 42, the earbud power source 43, the earbud speaker 44 and the earbud microphone 45 are electrically connected with one another. The earbud wireless module 42 is wirelessly coupled with the base wireless module 143 and/or the controller wireless module 212 and/or the remote wireless module 32, such that the earbud processing module 41 could process data transferred from and/or to the base processing module 141 and/or the controller processing module 211 and/or the remote processing module 31. The earbud power source 43 provides the energy necessary for operation of the earbud processing module 41, the earbud wireless module 42, the earbud speaker 44 and the earbud microphone 45. Further, the earbud power source 43 can be recharged when the wireless earbud device 4 is wirelessly coupled with the base unit 1, whether or not positioned into an earbud device dock 201, thanks to the wireless communication between the earbud wireless module 42 and the wireless power transfer unit 152. The earbud speaker 44 is used to delivering sound signals, while the earbud microphone 45 is used to receiving sound signals.

Specifically, the base wireless module 143, the controller wireless module 212, the remote wireless module 32 and the earbud wireless module 42 could be wirelessly coupled with one another.

Particularly, the wireless communication implemented by the portable entertainment system is through, but not limited to, Bluetooth connections, WiFi networks, cellular networks, or satellite networks.

Preferably, the handheld controller 2 also comprises a vibration engine for the purposes of haptic feedback; this improves tactile sensations, especially as related to playing video games or running other interactive programs via the present invention. In one embodiment, the handheld controller 2 comprises four vibrational motors 265. Two of the four vibrational motors 265 are located in between the analog sticks 263 and the first triggers 264. The other two of the vibrational motors 265 are located in between the analog sticks 263 and the buttons 261. The vibrational motor 265 is electrically connected with the controller processing module 211, the controller wireless module 212, the controller power source 213 and the remote connector 272.

In one embodiment, the handheld controller 2 comprises the earbud device dock 201 and an earbud device dock cover 202, the earbud device dock 201 is formed within at least one of the first grip 21 and the second grip 22, the earbud device dock cover 202 is rotatably connected with at least one of the first grip 21 and the second grip 22 so as to cover the earbud device dock 201. Accordingly, the wireless earbud device 4 could be positioned into the earbud device dock 201. In the embodiment that the wireless earbud device 4 has two earbuds, the earbud device dock 201 comprises two earbud docks and two earbud dock covers. One of the two earbud docks is formed within the first grip 21, while the other one of the two earbud docks is formed within the second grip 22. In this embodiment, the two of the vibrational motors 265 located in between the analog sticks 263 and the buttons 261 are located adjacent to the two earbud docks.

In one embodiment, the handheld controller 2 comprises a supporting frame 273 and a remote connector 272′. The supporting frame 273 is located adjacent to the recess 271. The remote connector 272′ is disposed on the supporting frame 273. The remote connector 272′ is electrically connected with the controller processing module 211, the controller wireless module 212, the controller power source 213, the remote connector 272 and the vibrational motor 265. The supporting frame 273 has two supporting elements rotatably and telescopingly connected with each other. Accordingly, another remote computing device 3′ could be placed on the supporting frame 273 and electrically connected with the remote connector 272′. The viewing angle of the another remote computing device 3′ could be regulated through the two supporting elements of the supporting frame 273 rotatably and telescopingly connected with each other. The another remote computing device 3′ is identical to the remote computing device 3. For example, the remote computing device 3′ comprises a remote processing module, a remote wireless module, a remote power source, an interfacing port and an interactive display. In one embodiment, the remote computing device 3 and the another remote computing device 3′ both are docked into the handheld controller 2, while the handheld controller 2 is docked into the base unit 1.

Although the invention has been explained in relation to its preferred embodiment, it is to be understood that many other possible modifications and variations can be made without departing from the spirit and scope of the invention as hereinafter claimed.

What is claimed is:

1. A portable entertainment system comprising:
a base unit;
a remote computing device;
the base unit comprising an electronics apparatus;
the electronics apparatus comprising a base processing module;
the base processing module comprising a base central processing unit and a base graphics processing unit;
the base central processing unit and the base graphics processing unit being electrically connected with each other;
the remote computing device comprising a remote processing module;
the remote processing module comprising a remote central processing unit and a remote graphics processing unit;
the remote central processing unit and the remote graphics processing unit being electrically connected with each other;
the base unit and the remote computing device being configured to be electrically connected with each other; and
in response to the base unit and the remote computing device being electrically connected with each other, the base central processing unit and the remote central processing unit being coupled with each other, the base graphics processing unit being active, and the remote graphics processing unit being inactive.

2. The portable entertainment system as claimed in claim 1 comprising:
the electronics apparatus comprising a base wireless module;
the base processing module and the base wireless module being electrically connected with each other;
the remote computing device comprising a remote wireless module;
the remote processing module and the remote wireless module being electrically connected with each other; and
the base central processing unit and the remote central processing unit being wirelessly coupled with each other by the base wireless module and the remote wireless module being wirelessly coupled with each other.

3. The portable entertainment system as claimed in claim 1 comprising:
the base unit comprising a base power apparatus;
the electronics apparatus and the base power apparatus being electrically connected with each other;
the base power apparatus comprising a wireless power transfer unit;
the remote computing device comprising a remote power source and a remote wireless module;
the remote processing module, the remote power source and the remote wireless module being electrically connected with one another; and
the remote power source being wirelessly charged via the wireless power transfer unit by the wireless power transfer unit and the remote wireless module being wirelessly coupled with each other.

4. The portable entertainment system as claimed in claim 3 comprising:
the base power apparatus comprising a power unit; and
the power unit and the wireless power transfer unit being electrically connected with each other.

5. The portable entertainment system as claimed in claim 1 comprising:
the base unit comprising a universal docking apparatus;
the universal docking apparatus and the electronics apparatus being electrically connected with each other;
the universal docking apparatus comprising a docking connector;
the remote computing device comprising an interfacing port;
the remote processing module and the interfacing port being electrically connected with each other; and
the base central processing unit and the remote central processing unit being coupled with each other by the docking connector and the interfacing port being coupled with each other.

6. The portable entertainment system as claimed in claim 6 comprising:
the base unit comprising a base power apparatus;
the universal docking apparatus, the electronics apparatus and the base power apparatus being electrically connected with one another;
the base power apparatus comprising a power unit;
the remote computing device comprising a remote power source;
the remote processing module, the remote power source and the interfacing port being electrically connected with one another; and
the remote power source being charged via the power unit by the docking connector and the interfacing port being coupled with each other.

7. The portable entertainment system as claimed in claim 1 comprising:
a handheld controller;
the handheld controller comprising a controller processing module;
the base unit, the handheld controller and the remote computing device being configured to be electrically connected with one another; and
in response to the base unit, the handheld controller and the remote computing device being electrically connected with one another, the base central processing unit, the controller processing module and the remote central processing unit being coupled with one another.

8. The portable entertainment system as claimed in claim 7 comprising:
the electronics apparatus comprising a base wireless module;
the base processing module and the base wireless module being electrically connected with each other;
the handheld controller comprising a controller wireless module;
the controller processing module and the controller wireless module being electrically connected with each other;
the remote computing device comprising a remote wireless module;
the remote processing module and the remote wireless module being electrically connected with each other; and
the base central processing unit, the controller processing module and the remote central processing unit being wirelessly coupled with one another by the base wireless module, the controller wireless module and the remote wireless module being wirelessly coupled with one another.

9. The portable entertainment system as claimed in claim 7 comprising:
the base unit comprising a base power apparatus;
the electronics apparatus and the base power apparatus being electrically connected with each other;
the base power apparatus comprising a wireless power transfer unit;
the handheld controller comprising a controller power source;
the controller processing module, the controller power source and the controller wireless module being electrically connected with one another; and
the controller power source being wirelessly charged via the wireless power transfer unit by the wireless power transfer unit and the controller wireless module being wirelessly coupled with each other.

10. The portable entertainment system as claimed in claim 9 comprising:
the base power apparatus comprising a power unit; and
the power unit and the wireless power transfer unit being electrically connected with each other.

11. The portable entertainment system as claimed in claim 7 comprising:
the handheld controller comprising a remote connector;
the remote connector and the controller processing module being electrically connected with each other;
the remote computing device comprising an interfacing port;
the remote processing module and the interfacing port being electrically connected with each other; and
the controller processing module and the remote processing module being coupled with each other by the remote connector and the interfacing port being electrically connected with each other.

12. The portable entertainment system as claimed in claim 11 comprising:
the electronics apparatus comprising a base wireless module;
the base processing module and the base wireless module being electrically connected with each other;
the handheld controller comprising a controller wireless module;
the controller processing module, the remote connector, the controller wireless module being electrically connected with one another; and
the base central processing unit and the controller processing module being wirelessly coupled with each other by the base wireless module and the controller wireless module being wirelessly coupled with each other.

13. The portable entertainment system as claimed in claim 12 comprising:
the base unit comprising a base power apparatus;
the electronics apparatus and the base power apparatus being electrically connected with each other;
the base power apparatus comprising a wireless power transfer unit;
the handheld controller comprising a controller power source;
the controller processing module, the controller power source and the controller wireless module being electrically connected with one another; and
the controller power source being wirelessly charged via the wireless power transfer unit by the wireless power transfer unit and the controller wireless module being wirelessly coupled with each other.

14. The portable entertainment system as claimed in claim 13 comprising:
the base power apparatus comprising a power unit; and
the power unit and the wireless power transfer unit being electrically connected with each other.

15. The portable entertainment system as claimed in claim 13 comprising:
the remote computing device comprising a remote power source;
the remote processing module, the remote power source and the interfacing port being electrically connected with one another; and
the remote power source being charged via the wireless power transfer unit by the wireless power transfer unit and the controller wireless module being wirelessly coupled with each other and the remote connector and the interfacing port being electrically connected with each other.

16. The portable entertainment system as claimed in claim 7 comprising:
a wireless earbud device;
the wireless earbud device comprising an earbud processing module;
the base unit, the handheld controller, the remote computing device and the wireless earbud device being configured to be electrically connected with one another; and
in response to the base unit, the handheld controller, the remote computing device and the wireless earbud device being electrically connected with one another, the base central processing unit, the controller processing module, the remote central processing unit and the earbud processing module being coupled with one another.

17. The portable entertainment system as claimed in claim 16 comprising:
the electronics apparatus comprising a base wireless module;
the base processing module and the base wireless module being electrically connected with each other;
the handheld controller comprising a controller wireless module;
the controller processing module and the controller wireless module being electrically connected with each other;
the remote computing device comprising a remote wireless module;
the remote processing module and the remote wireless module being electrically connected with each other;
the wireless earbud device comprising an earbud wireless module;
the earbud processing module and the earbud wireless module being electrically connected with each other; and
the base central processing unit, the controller processing module, the remote central processing unit and the earbud processing module being wirelessly coupled with one another by the base wireless module, the controller wireless module, the remote wireless module and the earbud wireless module being wirelessly coupled with one another.

18. The portable entertainment system as claimed in claim 16 comprising:
the base unit comprising a base power apparatus;
the electronics apparatus and the base power apparatus being electrically connected with each other;
the base power apparatus comprising a wireless power transfer unit;
the wireless earbud device comprising an earbud power source;
the earbud processing module, the earbud power source and the earbud wireless module being electrically connected with one another; and
the earbud power source being wirelessly charged via the wireless power transfer unit by the wireless power transfer unit and the earbud wireless module being wirelessly coupled with each other.

19. The portable entertainment system as claimed in claim 18 comprising:
the base power apparatus comprising a power unit; and
the power unit and the wireless power transfer unit being electrically connected with each other.

20. The portable entertainment system as claimed in claim 16 comprising:
the electronics apparatus comprising a base wireless module;
the base processing module and the base wireless module being electrically connected with each other;
the handheld controller comprising a controller wireless module and a remote connector;
the controller processing module, the controller wireless module and the remote connector being electrically connected with one another;
the remote computing device comprising a remote wireless module and an interfacing port;
the remote processing module, the remote wireless module and the interfacing port being electrically connected with one another;
the wireless earbud device comprising an earbud wireless module;
the earbud processing module and the earbud wireless module being electrically connected with each other;
the base central processing unit, the controller processing module and the earbud processing module being wirelessly coupled with one another by the base wireless module, the controller wireless module and the earbud wireless module being wirelessly coupled with one another;
the controller processing module and the remote processing module being wirelessly coupled with each other by the remote connector and the interfacing port being coupled with each other; and
the remote processing module and the earbud processing module being wirelessly coupled with each other by the remote wireless module and the earbud wireless module being wirelessly coupled with each other.

21. The portable entertainment system as claimed in claim 1 comprising:
The base unit comprising a cooling apparatus; and
the electronics apparatus and the cooling apparatus being electrically connected with each other.

22. The portable entertainment system as claimed in claim 21 comprising:
the base unit comprising a frame;
the cooling apparatus comprising a cooling fan and a heat fin;
the cooling fan and the heat fin being mounted to the frame.
